(19) United States
(12) Patent Application Publication
(10) Pub. No.: US 2025/0205731 A1
(43) Pub. Date: Jun. 26, 2025

(54) PEROVSKITE CRYSTAL DEPOSITION METHOD AND DEPOSITION APPARATUS

(71) Applicant: National Institute of Advanced Industrial Science and Technology, Tokyo (JP)

(72) Inventors: Kohei Yamamoto, Tsukuba-shi (JP); Takurou Murakami, Tsukuba-shi (JP); Yuuji Yoshida, Tsukuba-shi (JP)

(73) Assignee: National Institute of Advanced Industrial Science and Technology, Tokyo (JP)

(21) Appl. No.: 18/848,943

(22) PCT Filed: Mar. 3, 2023
(86) PCT No.: PCT/JP2023/007983

§ 371 Date: Sep. 20, 2024

(30) Foreign Application Priority Data
Mar. 24, 2022 (JP) 2022-047691

(51) Int. Cl. B05C 11/04; B05C 5/02; B05C 9/12; B05D 3/04; B05D 7/24

(52) U.S. Cl. CPC B05C 11/04; B05C 5/02; B05C 9/12; B05D 3/04; B05D 7/24

(57) ABSTRACT

The present invention makes it possible to rapidly deposit perovskite crystals while suppressing a decline in smoothness of a perovskite crystalline film. A perovskite crystal deposition apparatus comprises: a base body stage on which a base body is to be placed; a blade which is disposed so as to face the surface of the base body such that a gap is formed therebetween when the base body is placed on the base body stage; and a gas supply member that sprays a gas at a pressure of 0.3-0.6 MPa, a temperature of 25-200° C., and a flow rate of 30-40 L/min onto the surface of the base body With the deposition apparatus, a perovskite crystalline layer is obtained by spraying a gas from the gas supply member onto a precursor film that has been obtained by spreading a precursor solution of perovskite crystals on the base body using the blade.

This application is based on and claims the benefit of priority from Japanese Patent Application No. 2022-047691, filed on 24 Mar. 2022, the content of which is incorporated herein by reference.

### BACKGROUND OF THE INVENTION

### Field of the Invention

The present application relates to a method and an apparatus for depositing a perovskite crystal of a perovskite solar cell.

### Related Art

In recent years, attention has been paid to a perovskite solar cell in which a power generation layer is a perovskite crystal layer. When the perovskite crystal layer is formed by a spin coating method, it is difficult to increase an area thereof. The spin coating method cannot be applied to a roll-to-roll method. Furthermore, in the spin coating method, it is necessary to control crystal growth by dropping a poor solvent during spin coating of a precursor solution of a perovskite crystal. Therefore, there is a problem that the yield and the in-plane uniformity of the film thickness (smoothness of film) are reduced.

On the other hand, in Non-Patent Document 1, a precursor solution of a perovskite crystal is coated to a base material by a slot die method, and immediately thereafter, a nitrogen gas is blown to dry the precursor solution, thereby depositing the perovskite crystal. However, in the method of

Non-Patent Document 1, since a poor solvent is used as the precursor solution, the yield may be reduced considering influence on reproducibility. In addition, in the method of Non-Patent Document 1, a deposition rate is 7 mm/sec (0.42 m/min), and further improvement of the deposition rate is required for mass production.

Non-Patent Document 1: Adv. Mater., 2015, 27, 1241-1247.

### SUMMARY OF THE INVENTION

The present invention has been made in view of such circumstances, and an object thereof is to rapidly deposit a perovskite crystal while suppressing a reduction in smoothness of a perovskite crystal film.

### Means for Solving the Problems

A perovskite crystal deposition method according to an aspect of the present application includes a coating step of spreading a precursor solution of a perovskite crystal on a substrate to obtain a precursor film having a thickness of 130 μm or less, and a drying step of blowing a gas at a pressure of 0.3 MPa or more and 0.6 MPa or less, a temperature of 100° C. or higher and 200° C. or lower, and a flow rate of 30 L/min or more and 40 L/min or less onto the precursor film from above a surface of the precursor film during a movement at a speed of 0.6 m/min or more and 4 m/min or less in a direction along the surface of the precursor film, to obtain a perovskite crystal layer.

A perovskite crystal deposition method according to another aspect of the present application includes a coating step of spreading a precursor solution of a perovskite crystal on a substrate to obtain a precursor film having a thickness of 130 μm or less, and a drying step of blowing a gas at a pressure of 0.5 MPa or more and 0.6 MPa or less, a temperature of 25° C. or higher and 200° C. or lower, and a flow rate of 30 L/min or more and 40 L/min or less onto the precursor film from above a surface of the precursor film during a movement at a speed of 0.6 m/min or more and 4 m/min or less in a direction along the surface of the precursor film, to obtain a perovskite crystal layer.

A perovskite crystal deposition apparatus according to the present application includes a substrate stage on which a substrate is to be placed, a blade disposed to face the substrate stage such that a gap is formed between the blade and a surface of the substrate when the substrate is placed on the substrate stage, and a gas supply member configured to blow a gas at a pressure of 0.3 MPa or more and 0.6 MPa or less, a temperature of 25° C. or higher and 200° C. or lower, and a flow rate of 30 L/min or more and 40 L/min or less onto the surface of the substrate when the substrate is placed on the substrate stage, configured to move at a speed of 0.6 m/min or more and 4 m/min or less with respect to the substrate, and fixed to the blade, the gas being blown from the gas supply member onto a precursor film obtained by spreading a precursor solution of a perovskite crystal on the substrate by the blade, to obtain a perovskite crystal layer.

### Effects of the Invention

In the deposition method according to the present application, a gas at a pressure of 0.3 MPa or more and 0.6MPa or less, a temperature of 100° C. or higher and 200° C. or lower, and a flow rate of 30 L/min or more and 40 L/min or less, or a gas at a pressure of 0.5 MPa or more and 0.6 MPa or less, a temperature of 25° C. or higher and 200° C. or lower, and a flow rate of 30 L/min or more and 40 L/min or less is blown onto a precursor film having a thickness of 130 μm or less during a movement at a speed of 0.6 m/min or more and 4 m/min or less. In addition, in the deposition apparatus according to the present application, a gas at a pressure of 0.3 MPa or more and 0.6 MPa or less, a temperature of 25° C. or higher and 200° C. or lower, and a flow rate of 30 L/min or more and 40 L/min or less is blown onto a precursor film obtained by spreading a precursor solution of a perovskite crystal on a substrate by a blade during a movement at a speed of 0.6 m/min or more and 4 m/min or less with respect to the substrate.

Therefore, the perovskite crystal can be rapidly deposited. Moreover, the smoothness of the deposited perovskite crystal film is about the same as the smoothness of a perovskite crystal film deposited by a spin coating method. That is, with the perovskite crystal deposition method and the perovskite crystal deposition apparatus according to the present application, the perovskite crystal can be rapidly deposited while suppressing a reduction in smoothness of the perovskite crystal film.

### BRIEF DESCRIPTION OF THE DRAWINGS

FIG. 1 is a schematic cross-sectional view of a deposition apparatus according to an embodiment;

FIG. 2 is a schematic top view of the deposition apparatus according to the embodiment;

FIG. 3 is a schematic cross-sectional view of a deposition apparatus used in an example;

FIG. 4 is light absorption spectra of CsFAMAPbIBr layers of Experimental Examples 1 to 4;

FIG. 5 is fluorescence spectra of CsFAMAPbIBr layers of Experimental Example 1 and a comparative example;

FIG. 6 is light absorption spectra of the CsFAMAPbIBr layers of Experimental Example 1 and the comparative example;

FIG. 7 is fluorescence spectra of CsFAMAPbIBr layers of Experimental Examples 5 to 12;

FIG. 8 is light absorption spectra of the CsFAMAPbIBr layers of Experimental Examples 5 to 12;

FIG. 9 is fluorescence spectra of CsFAMAPbIBr layers of Experimental Examples 13 to 20;

FIG. 10 is light absorption spectra of the CsFAMAPbIBr layers of Experimental Examples 13 to 20;

FIG. 11 is fluorescence spectra of CsFAMAPbIBr layers of Experimental Examples 21 to 28;

FIG. 12 is light absorption spectra of the CsFAMAPbIBr layers of Experimental Examples 21 to 28;

FIG. 13 is fluorescence spectra of CsFAMAPbIBr layers of Experimental Examples 29 to 36; and FIG. 14 is light absorption spectra of the CsFAMAPbIBr layers of Experimental Examples 29 to 36.

### DETAILED DESCRIPTION OF THE INVENTION

A perovskite crystal deposition method and a perovskite crystal deposition apparatus according to the present application will be described below with reference to the drawings based on embodiments and examples. The perovskite crystal deposition apparatus in the drawings schematically represents the configuration thereof, and thus does not match a dimensional ratio of an actual deposition apparatus. In addition, the same reference numerals may be given to the same members, and redundant description will be appropriately omitted.

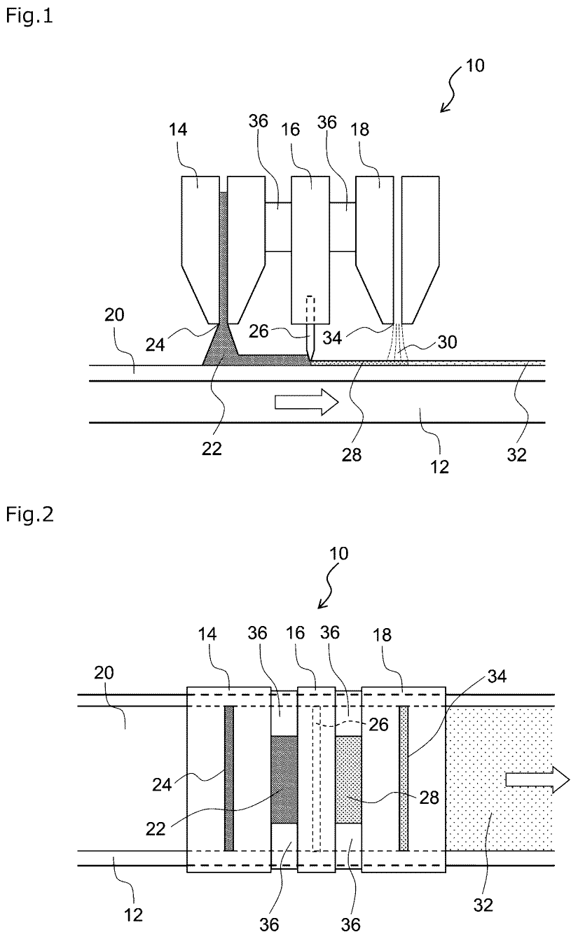

FIG. 1 schematically illustrates a cross section of a perovskite crystal deposition apparatus 10 (hereinafter, “perovskite crystal deposition apparatus 10” may be simply referred to as “deposition apparatus 10”) according to an embodiment of the present application. FIG. 2 schematically illustrates an upper surface of the deposition apparatus 10. The deposition apparatus 10 includes a substrate stage 12, a dropping member 14, a coating member 16, and a gas supply member 18. A substrate 20 is placed on the substrate stage 12. The deposition apparatus 10 is a roll-to-roll type deposition apparatus. The substrate stage 12 can move in an arrow direction at a speed of 0.6 m/min or more and 4 m/min or less. As the substrate stage 12 moves in the arrow direction, the substrate 20 also moves in the arrow direction, and an upper surface of the substrate 20 is processed by the dropping member 14, the coating member 16, and the gas supply member 18, which are fixed. Specific processing contents will be described later.

The dropping member 14 drops a precursor solution 22 of a perovskite crystal onto the substrate 20. In the present embodiment, the precursor solution 22 supplied from a tank (not illustrated) or the like to the dropping member 14 is dropped onto the substrate 20 through a slit 24 provided in a lower surface of the dropping member 14. The dropping member may have any structure as long as the precursor solution 22 can be dropped onto the substrate 20. For example, the dropping member may be a device that sprays the precursor solution 22 onto the substrate 20.

The coating member 16 includes a blade 26 on a lower surface thereof. The blade 26 spreads the precursor solution 22 of the perovskite crystal on the substrate 20 to form a precursor film 28. That is, the precursor film 28 is a thin film of the precursor solution 22, contains a moisture content, and is not crystallized perovskite. The blade 26 is made of a metal such as stainless steel. A material of the blade 26 is not particularly limited as long as the precursor film 28 can be formed by spreading the precursor solution 22. Examples of the material of the blade 26 include resin, rubber, and glass in addition to metal.

The blade 26 has a shape in which one side surface of a rectangular plate protrudes, and is installed such that a protruding surface faces downward. In the present embodiment, a lower surface of the blade 26 has a shape in which a distal end is flat and is narrowed toward a flat surface. In addition, the blade 26 is disposed to face the substrate 20 such that a gap is formed between the blade 26 and a surface of the substrate 20, that is, an upper surface of the substrate 20 when the substrate 20 is placed on the substrate stage 12. From the viewpoint of forming a good perovskite crystal film, the gap between the surface of the substrate 20 and the distal end of the blade 26 is preferably 25 μm or more and 500 μm or less, and more preferably 25 μm or more and 130 μm or less.

The gas supply member 18 blows a gas 30 supplied through a cylinder, a pipe, a compressor (all not illustrated) or the like toward the substrate stage 12. When the substrate 20 is placed on the substrate stage 12, the gas supply member 18 blows, onto the surface of the substrate 20, a gas at a pressure of 0.3 MPa or more and 0.6 MPa or less, a temperature of 100° C. or higher and 200° C. or lower, and a flow rate of 30 L/min or more and 40 L/min or less, or a gas at a pressure of 0.5 MPa or more and 0.6 MPa or less, a temperature of 25° C. or higher and 200° C. or lower, and a flow rate of 30 L/min or more and 40 L/min or less. A perovskite crystal layer 32 is obtained by blowing the gas 30 from the gas supply member 18 onto the precursor film 22.

In the present embodiment, nitrogen gas is blown through a slit 34 provided in a lower surface of the gas supply member 18. A type of the gas 30 is not limited as long as the perovskite crystal layer 32 can be obtained by blowing the gas 30 onto the precursor film 22. From the viewpoint of forming a good perovskite crystal film, preferable examples of the gas 30 include dry air containing only moisture whose dew point is below a freezing point, nitrogen, rare gases such as argon, and mixtures thereof.

In addition, the gas supply member 18 is fixed to the coating member 16, that is, to the blade 26 via a bonding member 36. Therefore, time from formation of the precursor film 28 to blowing of the gas 30 to the precursor film 28 becomes constant, and the homogeneous perovskite crystal layer 32 is obtained. The dropping member 14 and the coating member 16 are also fixed to each other via the bonding member 36. Furthermore, the gas supply member 18 can move at a speed of 0.6 m/min or more and 4 m/min or less with respect to the substrate 20.

In the present embodiment, the gas supply member

18 remains stationary, and the substrate stage 12 moves at a speed of 0.6 m/min or more and 4 m/min or less, so that the gas supply member 18 moves at a speed of 0.6 m/min or more and 4 m/min or less with respect to the substrate 20. The substrate stage remains stationary, and the gas supply member moves at a speed of 0.6 m/min or more and 4 m/min or less, so that the gas supply member moves at a speed of 0.6 m/min or more and 4 m/min or less with respect to the substrate.

A perovskite crystal deposition method (hereinafter, “perovskite crystal deposition method” may be simply referred to as “deposition method”) according to an embodiment of the present application includes a dropping step, a coating step, and a drying step. The deposition method according to the present application may be performed using the deposition apparatus 10, or may be performed using another apparatus. Hereinafter, the deposition method using the deposition apparatus 10 will be described as an example.

In the dropping step, the precursor solution 22 of a perovskite crystal is dropped from the dropping member 14 onto the substrate 20. In the coating step after the dropping step, the precursor solution 22 on the substrate 20 is spread by the blade 26 to obtain the precursor film 28 having a thickness of 130 μm or less. In the drying step after the coating step, the gas 30 at a pressure of 0.3 MPa or more and 0.6 MPa or less, a temperature of 100° C. or higher and 200° C. or lower, and a flow rate of 30 L/min or more and 40 L/min or less, or the gas 30 at a pressure of 0.5 MPa or more and 0.6MPa or less, a temperature of 25° C. or higher and 200° C. or lower, and a flow rate of 30 L/min or more and 40 L/min or less is blown from the gas supply member 18 onto the precursor film 28, that is, from above the surface of the precursor film 28, thereby obtaining the perovskite crystal layer 32.

At this time, the gas supply member 18 moves at a speed of 0.6 m/min or more and 4 m/min or less in the direction along the surface of the precursor film 28. However, this movement is a relative relation between the precursor film 28 and the gas supply member 18, and in the present embodiment, the gas supply member 18 remains stationary, and the precursor film 28, that is, the substrate 12 moves. It is preferable to spread the precursor solution 22 while moving the blade 26 at a speed of 0.6 m/min or more and 4 m/min or less in the direction along the surface of the precursor film 28. This is because the good perovskite crystal layer 32 can be rapidly deposited.

Furthermore, it is preferable that the gas 30 is blown onto the precursor film 28 while moving in synchronization with the blade 26. This is because the homogeneous perovskite crystal layer 32 is obtained. In the deposition apparatus 10, the dropping member 14, the coating member 16, and the gas supply member 18 are fixed at predetermined intervals. Therefore, the homogeneous perovskite crystal layer 32 can be rapidly deposited in the deposition method using the deposition apparatus 10.

### EXAMPLES

### Experimental Example 1

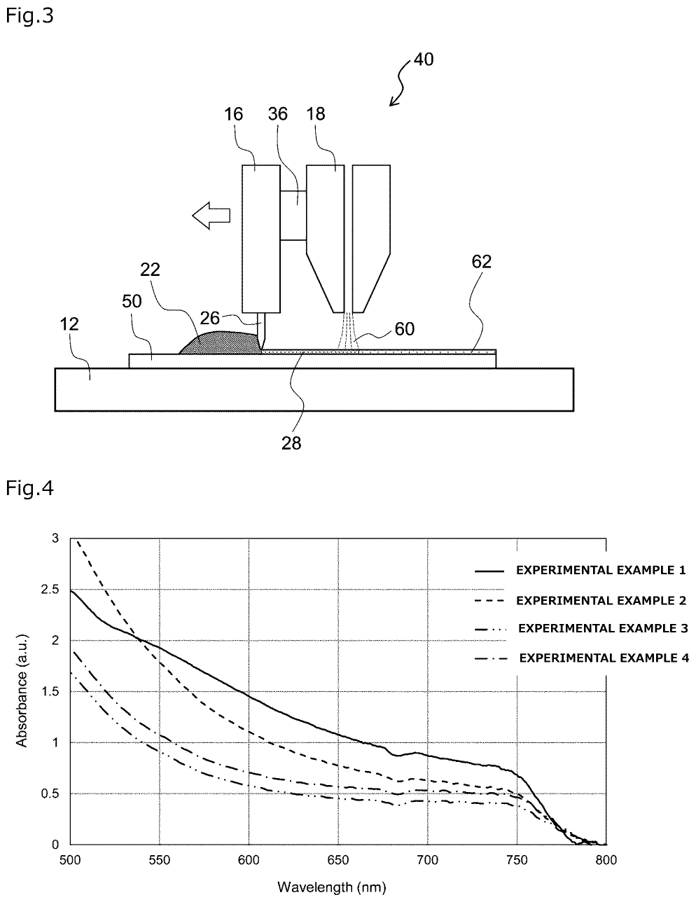

A Cs_{0.05} (FA_{0.89}MA_{0.11})_{0.95}Pb(I_{0.89}Br_{0.11})₃ (hereinafter, also referred to as “CsFAMAPbIBr”) layer 62 was deposited on a glass plate 50 by the following procedure using a deposition apparatus 40 illustrated in FIG. 3 (FA indicates Formamidinium, and MA indicates Methylamine). In the deposition apparatus 40, the substrate stage 12 and the glass plate 50 are stationary, and the coating member 16, that is, the blade 26 and the gas supply member 18 move synchronously in an arrow direction along guide rails (not illustrated) provided on both sides of the coating member 16 and the gas supply member 18.

In the example, the arrow direction in FIG. 3 is a longitudinal direction (longitudinal direction of glass plate 50 and longitudinal direction in which constituent members of deposition apparatus 40 move), and a direction orthogonal to the longitudinal direction on a plane on the glass plate 50 is a lateral direction of the glass plate 50. The blade 26 was obtained by processing one side surface of a stainless steel plate having a length of 30 mm, a width of 120 mm, and a thickness of 0.5 mm into an acute angle shape with a flat distal end, and the blade 26 was disposed such that a gap between a flat portion at the distal end and an upper surface of the glass plate 50 was 130 μm.

First, 123 mg of FAI, 382 mg of PbI₂, 14 mg of MABr, 36 mg of PbBr₂, and 29 μL of a DMSO solution (1.5 M) of CsI were dissolved in a mixed solution of 750 μL of DMF and 50 μL of DMSO to prepare the precursor solution 22 of CsFAMAPbIBr. Next, 40 μL of the precursor solution 22 was dropped in a straight line with a width of 100 mm and a length of 2 mm along the lateral direction on the glass plate 50 having a length of 100 mm, a width of 100 mm, and a thickness of 0.7 mm.

Then, the blade 26 was moved at 0.6 m/min in the longitudinal direction indicated by an arrow, and the precursor solution 22 was spread on the glass plate 50 to obtain the precursor film 28. At this time, a nitrogen gas 60 at a pressure of 0.5 MPa, a temperature of 125° C., and a flow rate of 40 L/min was blown onto the precursor film 28 from a laterally long slit (length of 0.3 mm and width of 120 mm) that moves in synchronization with the blade 26 and faces an upper surface of the glass plate 50. The precursor film 28 with the slit passed above was immediately crystallized to form the CsFAMAPbIBr layer of Experimental Example 1. The gas supply member 18 of the deposition apparatus 40 blows out a gas at a pressure of 0.6 MPa or less.

### Experimental Example 2

A CsFAMAPbIBr layer of Experimental Example 2 was formed in the same manner as Experimental Example 1 except that the moving speed of the blade 26 was changed to 1.2 m/min.

### Experimental Example 3

A CsFAMAPbIBr layer of Experimental Example 3 was formed in the same manner as Experimental Example 1 except that the moving speed of the blade 26 was changed to 3 m/min.

### Experimental Example 4

A CsFAMAPbIBr layer of Experimental Example 4 was formed in the same manner as Experimental Example 1 except that the moving speed of the blade 26 was changed to 4 m/min.

### Evaluation on Deposition in Experimental Examples 1 to 4

FIG. 4 illustrates light absorption spectra of the CsFAMAPbIBr layers of Experimental Examples 1 to 4. As illustrated in FIG. 4, the light absorption spectra match at an absorption edge in the vicinity of a wavelength of 780 nm. That is, regardless of the moving speed of the blade 26, the CsFAMAPbIBr layer of a perovskite crystal is deposited. In a pressure range of 0.6 MPa or less of the gas that may be supplied by the gas supply member 18 of the deposition apparatus 40, a tendency that a good crystal layer is obtained is observed in a case where the pressure of the gas blown onto the precursor film 28 is increased.

### Comparative Example

A CsFAMAPbIBr layer was deposited on a glass plate by a spin coating method according to the following procedure. First, 500 μL of the same precursor solution as in Experimental Example 1 was spin coated on the same glass plate as in Experimental Example 1 at 1,000 rpm for 10 seconds. Next, a small amount of chlorobenzene was further spin coated at 6,000 rpm for 20 seconds to obtain a uniform precursor film. Then, the precursor film was heated by a hot plate at 100° C. for 1 hour to form the CsFAMAPbIBr layer of the comparative example.

### Evaluation on Deposition in Experimental Example 1 and Comparative Example

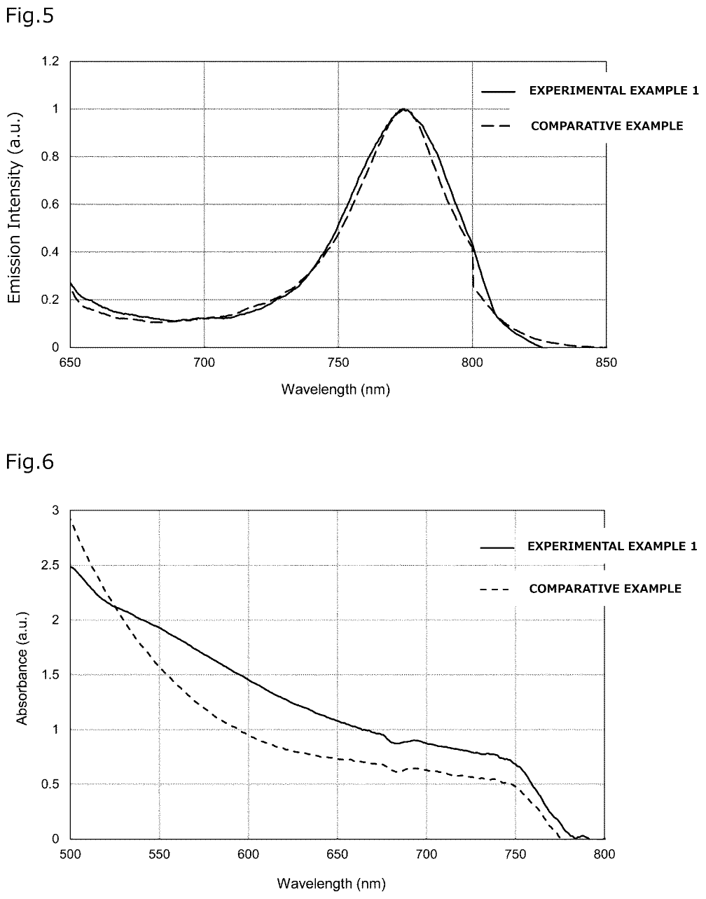

FIG. 5 illustrates fluorescence spectra of the CsFAMAPbIBr layers of Experimental Example 1 and the comparative example. FIG. 6 illustrates light absorption spectra of the CsFAMAPbIBr layers of Experimental Example 1 and the comparative example. As illustrated in FIG. 5, the fluorescence spectra of the CsFAMAPbIBr layers of Experimental Example 1 and the comparative example are almost the same. As illustrated in FIG. 6, shapes of the light absorption spectra of the CsFAMAPbIBr layers of Experimental Example 1 and the comparative example are similar. Therefore, it is found that the CsFAMAPbIBr layer of Experimental Example 1 is the same film as the CsFAMAPbIBr layer of the comparative example uniformly deposited by a spin coating method in the related art.

### Experimental Example 5

A CsFAMAPbIBr layer of Experimental Example 5 was formed in the same manner as Experimental Example 1 except that the pressure of the nitrogen gas was changed to 0.3 MPa, the temperature was changed to 25° C., and the flow rate was changed to 30 L/min.

### Experimental Example 6

A CsFAMAPbIBr layer of Experimental Example 6 was formed in the same manner as Experimental Example 5 except that the temperature of the nitrogen gas was changed to 50° C.

### Experimental Example 7

A CsFAMAPbIBr layer of Experimental Example 7 was formed in the same manner as Experimental Example 5 except that the temperature of the nitrogen gas was changed to 100° C.

### Experimental Example 8

A CsFAMAPbIBr layer of Experimental Example 8 was formed in the same manner as Experimental Example 5 except that the temperature of the nitrogen gas was changed to 125° C.

### Experimental Example 9

A CsFAMAPbIBr layer of Experimental Example 9 was formed in the same manner as Experimental Example 5 except that the temperature of the nitrogen gas was changed to 150° C.

### Experimental Example 10

A CsFAMAPbIBr layer of Experimental Example 10 was formed in the same manner as Experimental Example 5 except that the temperature of the nitrogen gas was changed to 175° C.

### Experimental Example 11

A CsFAMAPbIBr layer of Experimental Example 11 was formed in the same manner as Experimental Example 5 except that the temperature of the nitrogen gas was changed to 200° C.

### Experimental Example 12

A CsFAMAPbIBr layer of Experimental Example 12 was formed in the same manner as Experimental Example 5 except that the temperature of the nitrogen gas was changed to 260° C.

### Evaluation on Deposition in Experimental Examples 5 to 12

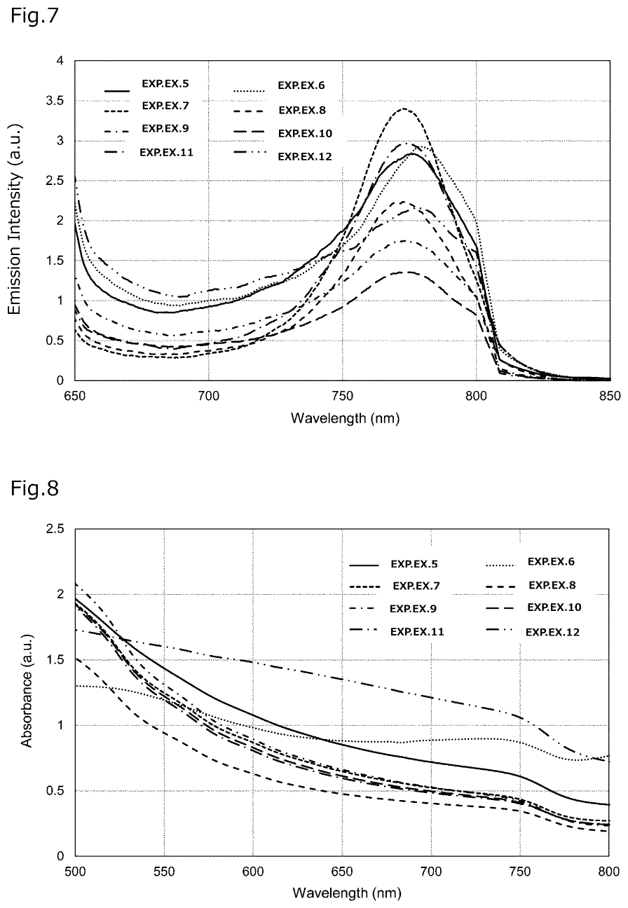

FIG. 7 illustrates fluorescence spectra of the CsFAMAPbIBr layers of Experimental Examples 5 to 12. It can be confirmed that the fluorescence spectra of the CsFAMAPbIBr layers of Experimental Examples 5, 6, and 12 are shifted to a long wavelength side. On the other hand, peak positions in the fluorescence spectra of the CsFAMAPbIBr layers of Experimental Examples 7 to 11 are equivalent to that of the comparative example prepared by a spin coating method.

FIG. 8 illustrates light absorption spectra of the CsFAMAPbIBr layers of Experimental Examples 5 to 12. In the light absorption spectra of the CsFAMAPbIBr layers of Experimental Examples 5, 6, and 12, a baseline of 780 nm to 800 nm deviates, and light scattering due to roughness of a surface of the CsFAMAPbIBr layer is confirmed. On the other hand, the light absorption spectra of the CsFAMAPbIBr layers of Experimental Examples 7 to 11 are equivalent to the light absorption spectrum of the CsFAMAPbIBr layer of the comparative example prepared by a spin coating method.

The surface roughness (RMS) of each of the CsFAMAPbIBr layers of Experimental Examples 5 to 12 and the comparative example was calculated from a profile when a stylus is operated in a width of 5 mm at an interference pressure of 1 mg using Dektak XT (manufactured by Bruker) (the same applies hereinafter). The RMS of the CsFAMAPbIBr layer of the comparative example is 18.226 nm. On the other hand, the RMS of the CsFAMAPbIBr layers of Experimental Examples 5, 6, and 12 is 24.670 nm to 37.226 nm. That is, the smoothness of the CsFAMAPbIBr layers of Experimental Examples 5, 6, and 12 is inferior to that of the CsFAMAPbIBr layer of the comparative example prepared by a spin coating method.

On the other hand, the RMS of the CsFAMAPbIBr layers of Experimental Examples 7 to 11 is 14.648 nm to 16.799 nm. That is, the smoothness of the CsFAMAPbIBr layers of Experimental Examples 7 to 11 is superior to that of the CsFAMAPbIBr layer of the comparative example prepared by a spin coating method. That is, when the pressure of the nitrogen gas is 0.3 MPa and the flow rate is 30 L/min, a CsFAMAPbIBr layer having excellent smoothness similar to that of the spin coating method cannot be deposited in cases where the temperature of the nitrogen gas is as low as 50° C. or lower and as high as 260° C.

### Experimental Example 13

A CsFAMAPbIBr layer of Experimental Example 13 was formed in the same manner as Experimental Example 1 except that the temperature of the nitrogen gas was changed to 25° C., and the flow rate was changed to 30 L/min.

### Experimental Example 14

A CsFAMAPbIBr layer of Experimental Example 14 was formed in the same manner as Experimental Example 13 except that the temperature of the nitrogen gas was changed to 50° C.

### Experimental Example 15

A CsFAMAPbIBr layer of Experimental Example 15 was formed in the same manner as Experimental Example 13 except that the temperature of the nitrogen gas was changed to 100° C.

### Experimental Example 16

A CsFAMAPbIBr layer of Experimental Example 16 was formed in the same manner as Experimental Example 13 except that the temperature of the nitrogen gas was changed to 125° C.

### Experimental Example 17

A CsFAMAPbIBr layer of Experimental Example 17 was formed in the same manner as Experimental Example 13 except that the temperature of the nitrogen gas was changed to 150° C.

### Experimental Example 18

A CsFAMAPbIBr layer of Experimental Example 18 was formed in the same manner as Experimental Example 13 except that the temperature of the nitrogen gas was changed to 175° C.

### Experimental Example 19

A CsFAMAPbIBr layer of Experimental Example 19 was formed in the same manner as Experimental Example 13 except that the temperature of the nitrogen gas was changed to 200° C.

### Experimental Example 20

A CsFAMAPbIBr layer of Experimental Example 20 was formed in the same manner as Experimental Example 13 except that the temperature of the nitrogen gas was changed to 260° C.

### Evaluation on Deposition in Experimental Examples 13 to 20

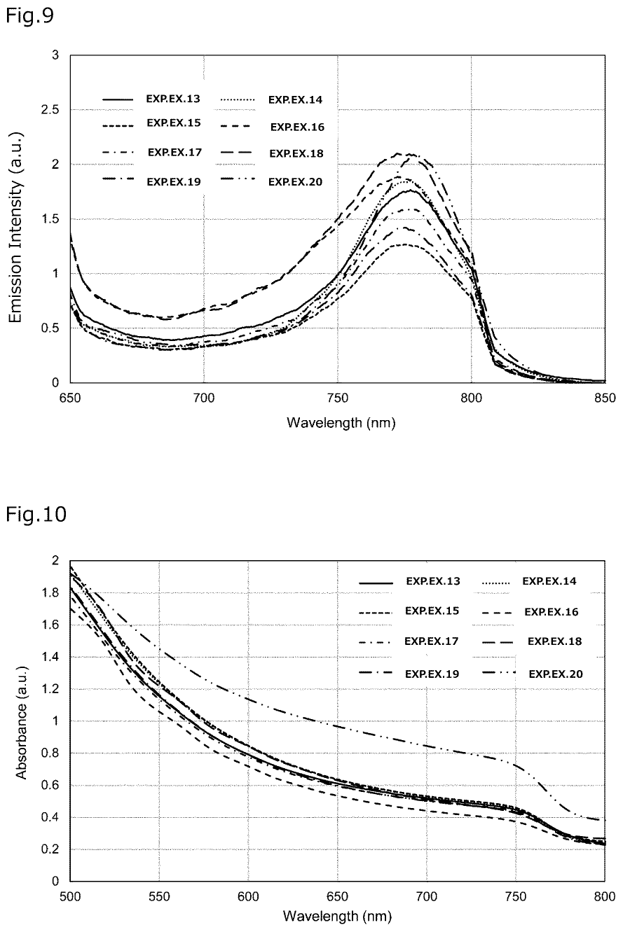

FIG. 9 illustrates fluorescence spectra of the CsFAMAPbIBr layers of Experimental Examples 13 to 20. The fluorescence spectrum of the CsFAMAPbIBr layer of Experimental Example 20 is shifted to a long wavelength side as compared with the fluorescence spectrum of the CsFAMAPbIBr layer of the comparative example prepared by a spin coating method. That is, in Experimental Example 20, a CsFAMAPbIBr layer equivalent to that of the comparative example is not obtained.

FIG. 10 illustrates light absorption spectra of the CsFAMAPbIBr layers of Experimental Examples 13 to 20. In the light absorption spectrum of the CsFAMAPbIBr layer of Experimental Example 20, a baseline of 770 nm to 800 nm is deflected upward, and light scattering due to the surface roughness of the CsFAMAPbIBr layer is confirmed.

In addition, according to RMS measurement results of the CsFAMAPbIBr layer, the smoothness of the CsFAMAPbIBr layer of Experimental Example 20 is inferior to that of the CsFAMAPbIBr layer of the comparative example prepared by a spin coating method, and the smoothness of the CsFAMAPbIBr layers of Experimental Examples 13 to 19 is identical with or superior to that of the CsFAMAPbIBr layer of the comparative example. That is, in a case where the temperature of the nitrogen gas is as high as 260° C., a CsFAMAPbIBr layer having excellent smoothness similar to that obtained by a spin coating method cannot be formed.

### Experimental Example 21

A CsFAMAPbIBr layer of Experimental Example 21 was formed in the same manner as Experimental Example 1 except that the pressure of the nitrogen gas was changed to 0.2 MPa, the temperature was changed to 25° C., and the flow rate was changed to 30 L/min.

### Experimental Example 22

A CsFAMAPbIBr layer of Experimental Example 22 was formed in the same manner as Experimental Example 21 except that the temperature of the nitrogen gas was changed to 50° C.

### Experimental Example 23

A CsFAMAPbIBr layer of Experimental Example 23 was formed in the same manner as Experimental Example 21 except that the temperature of the nitrogen gas was changed to 100° C.

### Experimental Example 24

A CsFAMAPbIBr layer of Experimental Example 24 was formed in the same manner as Experimental Example 21 except that the temperature of the nitrogen gas was changed to 125° C.

### Experimental Example 25

A CsFAMAPbIBr layer of Experimental Example 25 was formed in the same manner as Experimental Example 21 except that the temperature of the nitrogen gas was changed to 150° C.

### Experimental Example 26

A CsFAMAPbIBr layer of Experimental Example 26 was formed in the same manner as Experimental Example 21 except that the temperature of the nitrogen gas was changed to 175° C.

### Experimental Example 27

A CsFAMAPbIBr layer of Experimental Example 27 was formed in the same manner as Experimental Example 21 except that the temperature of the nitrogen gas was changed to 200° C.

### Experimental Example 28

A CsFAMAPbIBr layer of Experimental Example 28 was formed in the same manner as Experimental Example 21 except that the temperature of the nitrogen gas was changed to 260° C.

### Evaluation on Deposition in Experimental Examples 21 to 28

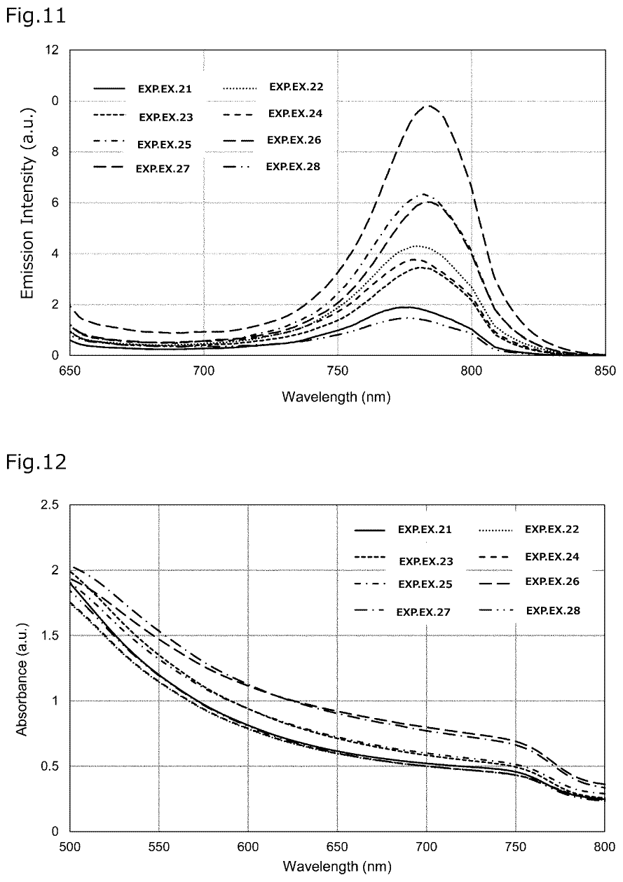

FIG. 11 illustrates fluorescence spectra of the CsFAMAPbIBr layers of Experimental Examples 21 to 28. The fluorescence spectra of the CsFAMAPbIBr layers of Experimental Examples 22 to 28 are shifted to a long wavelength side as compared with the fluorescence spectrum of the CsFAMAPbIBr layer of the comparative example prepared by a spin coating method. That is, in Experimental Examples 22 to 28, a CsFAMAPbIBr layer equivalent to that of the comparative example is not obtained.

FIG. 12 illustrates light absorption spectra of the CsFAMAPbIBr layers of Experimental Examples 21 to 28. In the light absorption spectra of the CsFAMAPbIBr layers of Experimental Examples 25 and 26, a baseline of 770 nm to 800 nm is deflected upward, and light scattering due to the surface roughness of the CsFAMAPbIBr layer is confirmed.

In addition, according to RMS measurement results of the CsFAMAPbIBr layer, the smoothness of the CsFAMAPbIBr layers of Experimental Examples 21 to 28 is inferior to that of the CsFAMAPbIBr layer of the comparative example prepared by a spin coating method. That is, in a case where the pressure of the nitrogen gas is as low as 0.2 Mpa, a CsFAMAPbIBr layer having excellent smoothness similar to that obtained by a spin coating method cannot be formed.

### Experimental Example 29

A CsFAMAPbIBr layer of Experimental Example 29 was formed in the same manner as Experimental Example 1 except that the pressure of the nitrogen gas was changed to 0.3 MPa, the temperature was changed to 25° C., and the flow rate was changed to 20 L/min.

### Experimental Example 30

A CsFAMAPbIBr layer of Experimental Example 30 was formed in the same manner as Experimental Example 29 except that the temperature of the nitrogen gas was changed to 50° C.

### Experimental Example 31

A CsFAMAPbIBr layer of Experimental Example 31 was formed in the same manner as Experimental Example 29 except that the temperature of the nitrogen gas was changed to 100° C.

### Experimental Example 32

A CsFAMAPbIBr layer of Experimental Example 32 was formed in the same manner as Experimental Example 29 except that the temperature of the nitrogen gas was changed to 125° C.

### Experimental Example 33

A CsFAMAPbIBr layer of Experimental Example 33 was formed in the same manner as Experimental Example 29 except that the temperature of the nitrogen gas was changed to 150° C.

### Experimental Example 34

A CsFAMAPbIBr layer of Experimental Example 34 was formed in the same manner as Experimental Example 29 except that the temperature of the nitrogen gas was changed to 175° C.

### Experimental Example 35

A CsFAMAPbIBr layer of Experimental Example 35 was formed in the same manner as Experimental Example 29 except that the temperature of the nitrogen gas was changed to 200° C.

### Experimental Example 36

A CsFAMAPbIBr layer of Experimental Example 36 was formed in the same manner as Experimental Example 29 except that the temperature of the nitrogen gas was changed to 260° C.

### Evaluation on Deposition in Experimental Examples 29 to 36

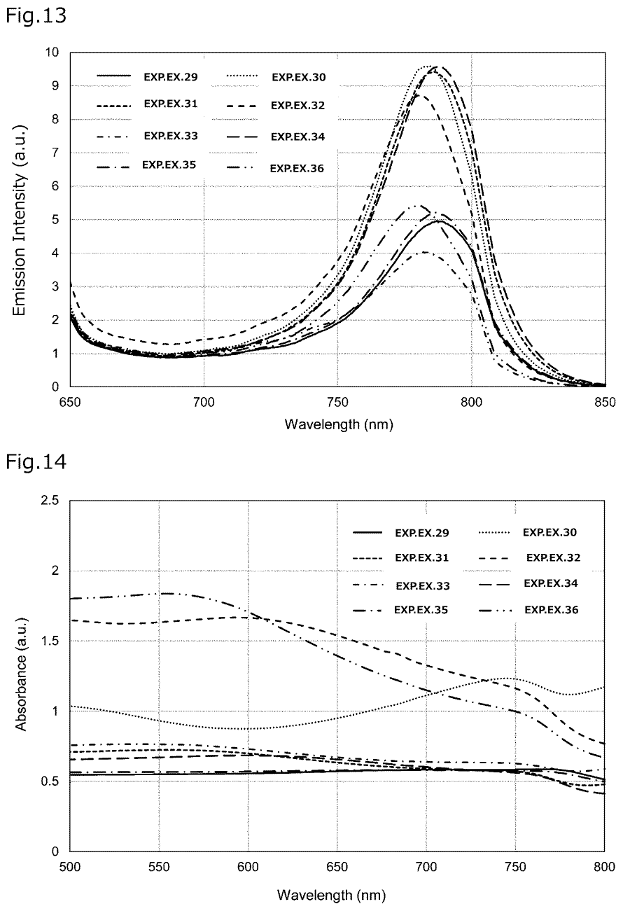

FIG. 13 illustrates fluorescence spectra of the CsFAMAPbIBr layers of Experimental Examples 29 to 36. The fluorescence spectra of the CsFAMAPbIBr layers of Experimental

Examples 29 to 36 are shifted to a long wavelength side as compared with the fluorescence spectrum of the CsFAMAPbIBr layer of the comparative example prepared by a spin coating method. That is, in Experimental Examples 29 to 36, a CsFAMAPbIBr layer equivalent to that of the comparative example is not obtained.

FIG. 14 illustrates light absorption spectra of the CsFAMAPbIBr layers of Experimental Examples 29 to 36. In the light absorption spectra of the CsFAMAPbIBr layers of Experimental Examples 30, 31, and 36, a baseline of 770 nm to 800 nm is deflected upward, and light scattering due to the surface roughness of the CsFAMAPbIBr layer is confirmed. Furthermore, in the light absorption spectra of the CsFAMAPbIBr layers of Experimental Examples 29 and 32 to 35, an absorption edge derived from the CsFAMAPbIBr film in the vicinity of 750 nm to 770 nm is not confirmed.

In addition, according to RMS measurement results of the CsFAMAPbIBr layer, the smoothness of the CsFAMAPbIBr layers of Experimental Examples 29 to 36 is inferior to that of the CsFAMAPbIBr layer of the comparative example prepared by a spin coating method. That is, in a case where the flow rate of the nitrogen gas is as less as 20 L/min, a CsFAMAPbIBr layer having excellent smoothness similar to that obtained by a spin coating method cannot be formed.

### EXPLANATION OF REFERENCE NUMERALS

10, 40: deposition apparatus

12: substrate stage
14: dropping member
16: coating member
18: gas supply member
20: substrate
22: precursor solution
24, 34: slit
26: blade
28: precursor film
30: gas
32: perovskite crystal layer
36: bonding member
50: glass plate
60: nitrogen gas
62: CsFAMAPbIBr layer

1. A perovskite crystal deposition method comprising:
a coating step of spreading a precursor solution of a perovskite crystal on a substrate to obtain a precursor film having a thickness of 130 μm or less; and
a drying step of blowing a gas at a pressure of 0.3 MPa or more and 0.6 MPa or less, a temperature of 100° C. or higher and 200° C. or lower, and a flow rate of 30 L/min or more and 40 L/min or less onto the precursor film from above a surface of the precursor film during a movement at a speed of 0.6 m/min or more and 4 m/min or less in a direction along the surface of the precursor film, to obtain a perovskite crystal layer.

2. A perovskite crystal deposition method comprising:
a coating step of spreading a precursor solution of a perovskite crystal on a substrate to obtain a precursor film having a thickness of 130 μm or less; and
a drying step of blowing a gas at a pressure of 0.5 MPa or more and 0.6 MPa or less, a temperature of 25° C. or higher and 200° C. or lower, and a flow rate of 30 L/min or more and 40 L/min or less onto the precursor film from above a surface of the precursor film during a movement at a speed of 0.6 m/min or more and 4 m/min or less in a direction along the surface of the precursor film, to obtain a perovskite crystal layer.

3. The perovskite crystal deposition method according to claim 1, further comprising:
a dropping step of dropping the precursor solution of the perovskite crystal on the substrate before the coating step.

4. The perovskite crystal deposition method according to claim 1, wherein
in the coating step, the precursor solution is spread by a blade.

5. The perovskite crystal deposition method according to claim 4, wherein
the precursor solution is spread while moving the blade at a speed of 0.6 m/min or more and 4 m/min or less in the direction along the surface of the precursor film.

6. The perovskite crystal deposition method according to claim 5, wherein
the gas is blown onto the precursor film while moving in synchronization with the blade.

7. A perovskite crystal deposition apparatus comprising: a substrate stage on which a substrate is to be placed;
a blade disposed to face the substrate stage such that a gap is formed between the blade and a surface of the substrate when the substrate is placed on the substrate stage; and
a gas supply member configured to blow a gas at a pressure of 0.3 MPa or more and 0.6 MPa or less, a temperature of 25° C. or higher and 200° C. or lower, and a flow rate of 30 L/min or more and 40 L/min or less onto the surface of the substrate when the substrate is placed on the substrate stage, configured to move at a speed of 0.6 m/min or more and 4 m/min or less with respect to the substrate, and fixed to the blade,
the gas being blown from the gas supply member onto a precursor film obtained by spreading a precursor solution of a perovskite crystal on the substrate by the blade, to obtain a perovskite crystal layer.

8. The perovskite crystal deposition apparatus according to claim 7, further comprising:
a dropping member configured to drop the precursor solution of the perovskite crystal on the substrate.

9. The perovskite crystal deposition apparatus according to claim 7, wherein
the substrate stage is movable at a speed of 0.6 m/min or more and 4 m/min or less.

10. The perovskite crystal deposition method according to claim 2, further comprising:
a dropping step of dropping the precursor solution of the perovskite crystal on the substrate before the coating step.

11. The perovskite crystal deposition method according to claim 2, wherein
in the coating step, the precursor solution is spread by a blade.

12. The perovskite crystal deposition apparatus according to claim 8, wherein
the substrate stage is movable at a speed of 0.6 m/min or more and 4 m/min or less.
